(19) United States
(12) Patent Application Publication
(10) Pub. No.: US 2025/0391467 A1
(43) Pub. Date: Dec. 25, 2025

(54) COMPOUND SEMICONDUCTOR BASED RANDOM ACCESS MEMORY

(71) Applicant: Wisconsin Alumni Research Foundation, Madison, WI (US)

(72) Inventors: Zihan Yin, Madison, WI (US); Akhilesh Jaiswal, Madison, WI (US); Chirag Gupta, Middleton, WI (US)

(21) Appl. No.: 18/752,047

(22) Filed: Jun. 24, 2024

(51) Int. Cl. G11C 11/412; G11C 11/419; H10B 10/00

(52) U.S. Cl. CPC G11C 11/412; G11C 11/419; H10B 10/12

(57) ABSTRACT

An SRAM cell includes a first transistor, a second transistor, a third transistor, a fourth transistor, a first inverter connected to a first input node and either the first transistor or the second transistor, a second inverter connected to a second input node and either the third transistor or the fourth transistor, a first access transistor connected between a first bit line and the first output node, and a second access transistor connected between a second bit line and the second output node. Each of the first transistor, the second transistor, the third transistor, the fourth transistor, the first access transistor, and the second access transistor is a gallium nitride (GaN) transistor and each of the first inverter and the second inverter comprises GaN transistors. The SRAM cell provides either RAM or ROM functionality.

### BACKGROUND

Memory devices are used in a variety of applications. Memory devices may include a plurality of memory cells. The plurality of memory cells may be arranged in an array of a plurality of rows and a plurality of columns. Memory cells may be of a variety of types. One example of a type of memory cell is Static Random Access Memory (SRAM). In some applications, SRAM based memory devices may be preferable due to faster speed and lower power consumption of SRAM cells. SRAM cells are made of silicon (Si) based transistors. While Si based transistors are suitable for operation at normal (e.g., room) temperatures, the operation of Si based transistors, and therefore, operation of SRAM cells, may break down at high or extremely high temperatures that may be required in certain applications where SRAM may be used. Thus, SRAM is limited in its configuration and the way SRAM cells operate.

### SUMMARY

In accordance with some embodiments of the present disclosure, a Static Random Access Memory (SRAM) cell is disclosed. The SRAM cell includes a first transistor connected between at least one supply voltage and a first output node, a second transistor connected between the first output node and a ground voltage, a third transistor connected between the at least one supply voltage and a second output node, a fourth transistor connected between the second output node and the ground voltage, a first inverter having a first inverter input and a first inverter output, the first inverter input connected to a first input node and the first inverter output connected to either the first transistor or the second transistor, a second inverter having a second inverter input and a second inverter output, the second inverter input connected to a second input node and the second inverter output connected to either the third transistor or the fourth transistor, a first access transistor connected between a first bit line and the first output node, and a second access transistor connected between a second bit line and the second output node. Each of the first transistor, the second transistor, the third transistor, the fourth transistor, the first access transistor, and the second access transistor is a gallium nitride (GaN) transistor and each of the first inverter and the second inverter includes GaN transistors.

In accordance with some other embodiments of the present disclosure, a Static Random Access Memory (SRAM) array is disclosed. The SRAM array includes a plurality of SRAM cells arranged in a plurality of rows and a plurality of columns, each of the plurality of SRAM cells having a first transistor connected between at least one supply voltage and a first output node, a second transistor connected between the first output node and a ground voltage, a third transistor connected between the at least one supply voltage and a second output node, a fourth transistor connected between the second output node and the ground voltage, a first inverter having a first inverter input and a first inverter output, the first inverter input connected to a first input node and the first inverter output connected to either the first transistor or the second transistor, a second inverter having a second inverter input and a second inverter output, the second inverter input connected to a second input node and the second inverter output connected to either the third transistor or the fourth transistor, a first access transistor connected between a first bit line and the first output node, and a second access transistor connected between a second bit line and the second output node. Each of the first transistor, the second transistor, the third transistor, the fourth transistor, the first access transistor, and the second access transistor is a gallium nitride (GaN) transistor and each of the first inverter and the second inverter includes GaN transistors.

In accordance with some embodiments of the present disclosure, a Static Random Access Memory (SRAM) cell is disclosed. The SRAM cell includes a first inverter having a first transistor connected between a supply voltage and a first output node, a second transistor connected to the first transistor via the first output node, and a third transistor connected between the second transistor and a ground voltage. The SRAM cell also includes a second inverter having a fourth transistor connected between the supply voltage and a second output node, a fifth transistor connected to the fourth transistor via the second output node, and a sixth transistor connected between the fifth transistor and the ground voltage. The SRAM cell further includes a first access transistor connected between the first output node and a first bit line and a second access transistor connected between the second output node and a second bit line. The third transistor and the sixth transistor are always enabled and each of the first transistor, the second transistor, the third transistor, the fourth transistor, the fifth transistor, the sixth transistor, the first access transistor, and the second access transistor is a gallium nitride (GaN) transistor.

Other principal features of the disclosed subject matter will become apparent to those skilled in the art upon review of the following drawings, the detailed description, and the appended claims.

### BRIEF DESCRIPTION OF THE DRAWINGS

Illustrative embodiments of the disclosed subject matter will hereafter be described referring to the accompanying drawings, wherein like numerals denote like elements.

FIG. 1 shows an example SRAM device, in accordance with some embodiments of the present disclosure.

FIG. 2 shows an example SRAM cell of the SRAM device of FIG. 1, in accordance with some embodiments of the present disclosure.

FIG. 3 shows an example shadow inverter of the SRAM cell of FIG. 2, in accordance with some embodiments of the present disclosure.

FIG. 4 shows another example SRAM cell of the SRAM device of FIG. 1, in accordance with some embodiments of the present disclosure.

FIG. 5 shows another example SRAM cell of the SRAM device of FIG. 1, in accordance with some embodiments of the present disclosure.

FIG. 6 shows yet another example SRAM cell of the SRAM device of FIG. 1, in accordance with some embodiments of the present disclosure.

FIG. 7 shows yet another example SRAM cell of the SRAM device of FIG. 1, in accordance with some embodiments of the present disclosure

FIG. 8 shows an example structure of a gallium nitride (GaN) transistor to be used in forming the various transistors of the SRAM cells of FIGS. 2 and 3-7, as well as the shadow inverter of FIG. 2, in accordance with some embodiments of the present disclosure.

FIG. 9A shows an n-channel GaN transistor based on the structure of FIG. 8, in accordance with some embodiments of the present disclosure.

FIG. 9B shows a p-channel GaN transistor based on the structure of FIG. 8, in accordance with some embodiments of the present disclosure.

FIG. 10 shows another example structure of a GaN transistor to be used in forming the various transistors of the SRAM cells of FIGS. 2 and 3-7, as well as the shadow inverter of FIG. 2, in accordance with some embodiments of the present disclosure.

FIG. 11A shows an n-channel GaN transistor based on the structure of FIG. 10, in accordance with some embodiments of the present disclosure.

FIG. 11B shows a first example of a p-channel GaN transistor based on the structure of FIG. 10, in accordance with some embodiments of the present disclosure.

FIG. 11C shows a second example of a p-channel GaN transistor based on the structure of FIG. 10, in accordance with some embodiments of the present disclosure.

### DETAILED DESCRIPTION

The present disclosure is directed to memory devices and more particularly to memory devices configured to function at high or extremely high temperatures. The memory devices of the present disclosure use compound semiconductors such as gallium nitride (GaN) to create transistors that are capable of functioning at high or extremely high temperatures. The GaN transistors are then used to create new forms of memory that may be accessed individually. More particularly, the present disclosure is directed to Static Random Access Memory (SRAM) having GaN transistors that allow the SRAM to function at high (e.g., greater than 300° Celsius) or extremely high (e.g., greater than 500° Celsius) temperatures.

At these high or extremely high temperatures, Si based SRAM solutions do not work. Compound semiconductors, like GaN, are promising candidates for harsh environment electronics due to their material properties. However, challenges remain because Complementary Metal-Oxide-Semiconductor (CMOS) based circuit design does not readily translate to simply replacing Si based transistors to GaN based transistors. Specifically, due to varying material properties and different voltage transfer characteristics, a Si based transistor may not be simply replaced with a GaN transistor. Further, because the mobility difference in an n-type GaN transistor and a p-type GaN transistor is much more compared to the mobility difference between an n-type Si transistor and a p-type Si transistor, a Si transistor may not be replaced simply with a GaN transistor. Therefore, new circuit designs are needed to allow use of GaN transistors to replace Si transistors in SRAM.

The present disclosure provides various circuit designs that use GaN transistors in SRAM technology. These circuit designs leverage inverters instead of wires that traditionally connect transistors. The circuit designs of the present disclosure may be used for creating SRAM devices configured to function at high or extremely high temperatures. Such SRAM devices may be used in any application where the SRAM device may be exposed to high or extremely high temperatures. Examples of such applications may be space, defense, nuclear reactors, etc.

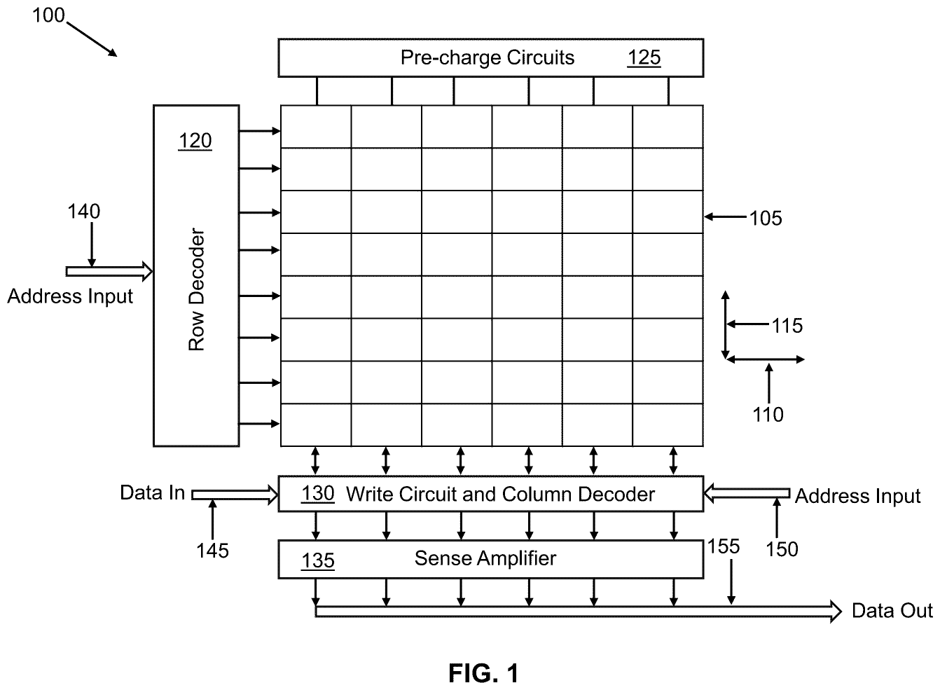

Referring now to FIG. 1, an example SRAM device 100 is shown, in accordance with some embodiments of the present disclosure. The SRAM device 100 includes an SRAM array 105 having a plurality of SRAM cells arranged in a matrix of a plurality of rows and a plurality of columns. Each SRAM cell of the plurality of SRAM cells may be configured to store a single bit of data. As used herein, a row extends along an X-direction 110 (also referred to herein as a row direction or a word-line direction) and a column extends along a Y-direction 115 (also referred to herein as a column direction or a bit-line direction). The number of the plurality of rows and the number of the plurality of columns may vary from one embodiment to another depending upon the size of the SRAM array 105 that is desired. Thus, although the SRAM array 105 is shown as an 8×6 array (e.g., having SRAM cells arranged in 8 rows and across 6 columns), in other embodiments, the SRAM array may be of any size and include any number of rows and/or columns.

Each SRAM cell of the SRAM array 105 may be connected to at least one word line that extends in the X-direction 110 and at least one bit line that extends in the Y-direction 115. In particular, each SRAM cell in the same row of the SRAM array 105 may be connected to the same word line(s) and each SRAM cell in the same column of the SRAM array may be connected to the same bit line(s). Thus, the SRAM array 105 may include a plurality of word lines and a plurality of bit lines. A “word line” may be considered a conductive line through which a voltage signal of an appropriate voltage level may be applied to the SRAM cell to which the word line is connected. By applying the voltage signal of the appropriate voltage level, the word line may be “asserted” to select the SRAM cell for either reading data from the SRAM cell or writing data to that SRAM cell. A “bit line” may be considered a conductive line that reads data from the SRAM cell that has been selected by the word line or that provides data to be written to the SRAM cell that has been selected by the word line. Thus, the word line selects an SRAM cell before data can be read from or written to that SRAM cell and the bit line provides the data read from or to be written to that SRAM cell.

The SRAM device 100 may also include a row decoder 120, pre-charge circuits 125, write circuit and column decoder 130, as well as sense amplifier 135 operably coupled to the SRAM array 105. The row decoder 130 may be used to select a particular word line of the SRAM array 105. For example, the row decoder 120 may receive an address input 140. The address input 140 may indicate the row to be asserted for reading or writing. The row decoder 130 may convert the address input 140 into an appropriate binary address for the word line to be asserted. For example, in some embodiments, upon conversion of the address input 140, the word line to be asserted may be represented by a high bit (e.g., 1) and the remaining word lines may be represented by a low bit (e.g., 0). In some embodiments, the row decoder 120 may be associated with additional or other types or circuits or elements that facilitate selection of a word line.

The pre-charge circuits 125 may be used to pre-charge the bit lines of the SRAM array 105 to a particular voltage before reading data from, or writing data to, the SRAM cells. By pre-charging the bit lines before reading or writing, the SRAM cells may be primed to a steady state. The SRAM device 100 may also include the write circuit and column decoder 130 and the sense amplifier 135. Although the write circuit and column decoder 130 are shown as a single component, in some embodiments, the write circuit and the column decoder may be separate components. In some embodiments, the write circuit may be used to receive data 145 to be written into the SRAM array 105. The column decoder may be used to select one or more columns (e.g., bit lines) in response to an address input 150. The sense amplifier 135 may be used to read data from particular SRAM cells of the SRAM array 105 via the bit line(s). For example, in some embodiments, data 155 being read from the SRAM array 105 may be sensed by the sense amplifier 140. In some embodiments, the write circuit and column decoder 130 and the sense amplifier 135 may be associated with latches and/or other circuits that enable reading data from and writing data to a particular SRAM cell. In some embodiments, the write circuit and column decoder 130, the sense amplifier 135, and other associated circuits (e.g., write drivers) that receive the read data or provide the write data may be considered input/output circuits.

The SRAM device 100 may additionally include a control circuit (not shown) that may be configured to control operation of the row decoder 120, the pre-charge circuits 125, the write circuit and column decoder 130, the sense amplifier 135, and any other circuits of the SRAM device. It is to be understood that only some components of the SRAM device 100 are shown in FIG. 1. In other embodiments, the SRAM device 100 may include other or additional components that are needed or considered desirable to have in operating the SRAM device and performing the functions described herein.

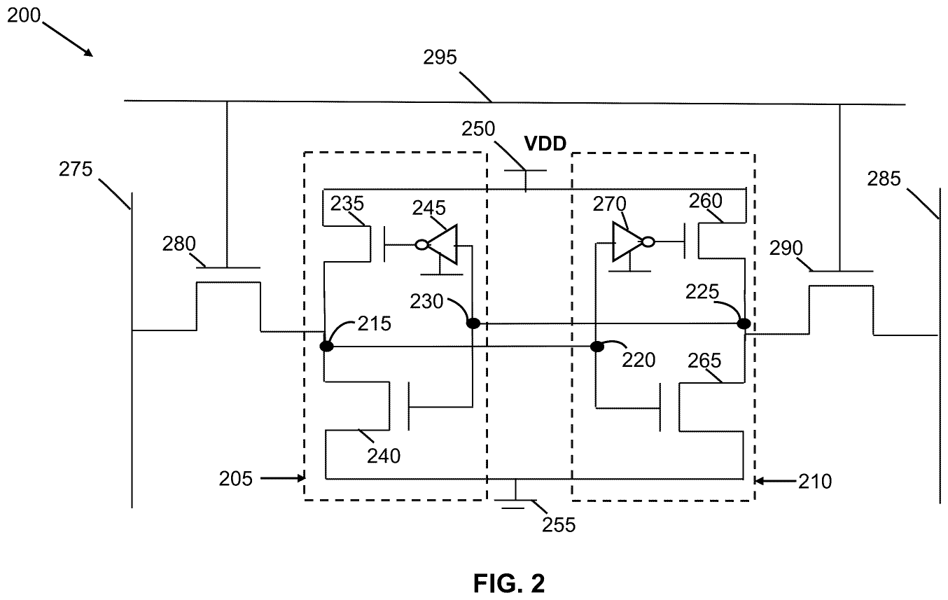

Turning to FIG. 2, an example SRAM cell 200 of the SRAM array 105 is shown, in accordance with some embodiments of the present disclosure. The SRAM cell 200 includes GaN transistors. Thus, the SRAM cell 200 may be used at high or extremely high temperatures. The SRAM cell 200 includes two cross-coupled sub-circuits 205 and 210 that form a latch circuit. Cross-coupling the sub-circuits 205 and 210 means that an output node 215 of the sub-circuit 205 is connected to an input node 220 of the sub-circuit 210 and an output node 225 of the sub-circuit 210 is connected to an input node 230 of the sub-circuit 205 such that when one of the output nodes (e.g., the output node 215 or the output node 225) is pulled to a low voltage level (also referred to herein as being pulled low or pulled down), the other output node transitions to a high voltage level (also referred to herein as being pulled high or pulled up). The sub-circuit 205 includes a first transistor 235, a second transistor 240, and a first inverter 245 connected between a supply voltage 250 (e.g., VDD, CVDD, 5 volts, 3.3 volts, 1.8 volts, etc.) and a ground voltage 255 (e.g., VSS, Negative VSS, 0 volts, etc.). The sub-circuit 210 includes a third transistor 260, a fourth transistor 265, and a second inverter 270 connected between the supply voltage 250 and the ground voltage 255.

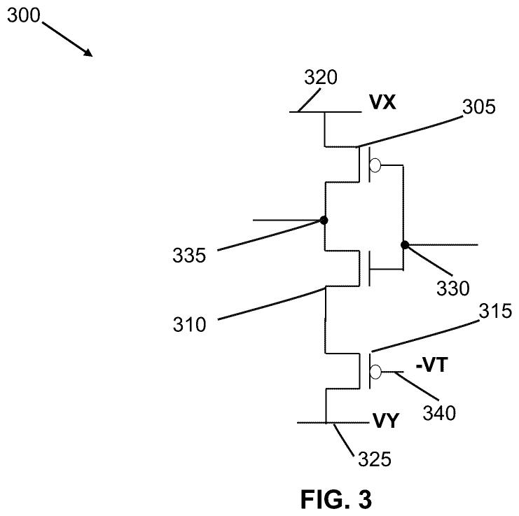

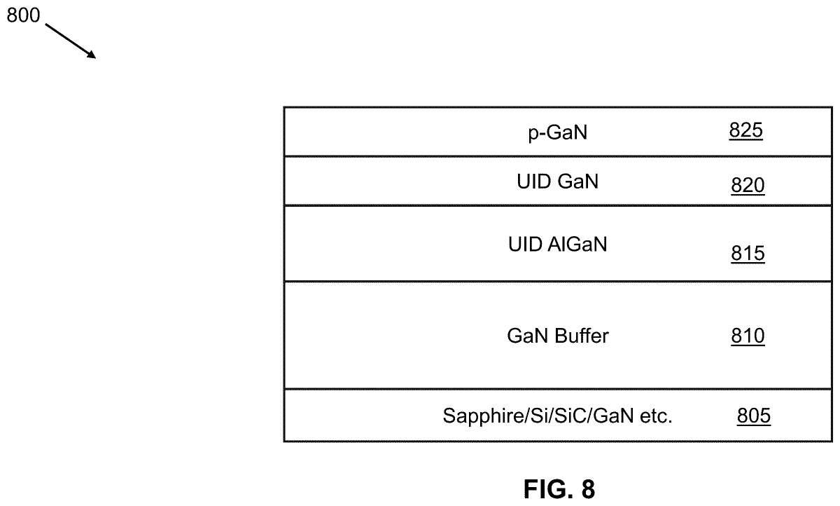

Each of the first transistor 235, the second transistor 240, the third transistor 260, the fourth transistor 265, the first inverter 245, and the second inverter 270 may be a GaN transistor. Example structures of the GaN transistor are shown/described in FIGS. 8-11C. The first inverter 245 and the second inverter 270 are referred to herein as shadow inverters and described in greater detail in FIG. 3. In some embodiments, each of the first transistor 235, the second transistor 240, the third transistor 260, and the fourth transistor 265 is a GaN n-type transistor (e.g., N-channel Metal Oxide Semiconductor (MOS) or NMOS). In some embodiments, the output of the first inverter 245 is connected to an input or first terminal (e.g., gate) of the first transistor 235. In some embodiments, a second terminal (e.g., source or drain) of the first transistor 235 is connected to the supply voltage 250 and a third terminal (e.g., drain or source) of the first transistor is connected to the output node 215. Thus, operation of the first transistor 235 is controlled by the output of the first inverter 245. Because the first transistor 235 is n-type, the first transistor may be enabled (e.g., turned on) when the output of the first inverter 245 is high or at a high voltage level (e.g., bit 1) and disabled (e.g., turned off) when the output of the first inverter is low or at a low voltage level (e.g., bit 0). When the first transistor 235 is enabled, the output node 215 is connected, and pulled up, to the supply voltage 250. When the first transistor 235 is disabled, the output node 215 is disconnected from the supply voltage 250.

The output of the first inverter 245 is controlled based on the input of the first inverter, which is connected to the input node 230. The input node 230 also connects to an input or first terminal (e.g., gate) of the second transistor 240. In some embodiments, a second terminal (e.g., source or drain) of the second transistor 240 is connected to the ground voltage 255 while a third terminal (e.g., drain or source) is connected to the output node 215. The operation of the second transistor 240 is controlled based on the voltage level at the input node 230. If the input node 230 is high or at a high voltage level (e.g., bit 1), the second transistor 240 is enabled and the output node 215 is connected to, and pulled down to, the ground voltage 255. If the input node 230 is low or at a low voltage level (e.g., bit 0), the second transistor 240 is disabled and the output node 230 is disconnected from the ground voltage 255.

Similarly, the output of the second inverter 270 is connected to an input or first terminal (e.g., gate) of the third transistor 260 and the input of the second inverter is connected to the input node 220. In some embodiments, a second terminal (e.g., source or drain) of the third transistor 260 is connected to the supply voltage 250 while a third terminal (e.g., drain or source) of the second transistor is connected to the output node 225. The operation of the third transistor 260 is controlled based on the output of the second inverter 270. When the output of the second inverter 270 is high or at a high voltage level, the third transistor 260 is enabled and the output node 225 is pulled up to the supply voltage 250 and when the output of the second inverter is low or at a low voltage level, that output node is disconnected from the supply voltage. In some embodiments, an input or first terminal (e.g., gate) of the fourth transistor 265 is connected to the input node 220, a second terminal (e.g., source or drain) of the fourth transistor is connected to the ground voltage 255, and a third terminal (e.g., drain or source) of the fourth transistor is connected to the output node 225. The fourth transistor 265 is controlled based on the voltage level at the input node 220. When the input node 220 is high or at a high voltage level, the fourth transistor 265 is enabled and the output node 225 is pulled down to the ground voltage 255. When the input node 220 is low or at a low voltage level, the fourth transistor 265 is disabled and the output node 225 is disconnected from the ground voltage 255.

The output node 215 and the output node 225 serve as storage nodes (e.g., from where data stored in the SRAM cell 200 is read or where data is written to). The output node 215 is coupled to a first bit line 275 through a first access transistor 280 and the output node 225 is coupled to a second bit line 285 through a second access transistor 290. The first bit line 275 and the second bit line 285 are the same but complementary lines, or in other words, inverse of one another. The gate terminals of the first access transistor 280 and the second access transistor 290, respectively, are connected to a word line 295.

The voltage level on the word line 295 enables or disables the first access transistor 280 and the second access transistor 290 to allow or deny, respectively, access to the output nodes 215 and 225. For example, when the word line 295 is asserted (e.g., by applying appropriate voltage or switching to a high voltage level (e.g., VDD)), the first access transistor 280 and the second access transistor 290 are enabled. When the first access transistor 280 and the second access transistor 290 are enabled, the SRAM cell 200 is considered selected. Further, when the first access transistor 280 and the second access transistor 290 are enabled, the output nodes 215 and 225 are accessible to the first bit line 275 and the second bit line 285, respectively. By being accessible to the first bit line 275 and the second bit line 285, data stored at the output nodes 215 and 225 may be respectively read by those bit lines. Similarly, by being accessible to the first bit line 275 and the second bit line 285, data on those bit lines may be written to the output nodes 215 and 225, respectively. When the word line 295 is de-asserted (e.g., by applying a low voltage level (e.g., Vss)), the first access transistor 280 and the second access transistor 290 are disabled and the output nodes 215 and 225 are disconnected from the first bit line 275 and the second bit line 285, respectively. When the output nodes 215 and 285 are disconnected from the first bit line 275 and the second bit line 285 respectively, data may not be read from or written to those output nodes. Thus, by adjusting the voltage level at the word line 295, data may be stored at or read from the output nodes 215 and 225.

When the output node 215 is low or at a low voltage level (e.g., storing bit 0) and the output node 225 is high or at a high voltage level (e.g., storing bit 1), the input node 220 is also low or at a low voltage level and the input node 230 is high or at a high voltage level. Thus, the input at the second inverter 270 and at the first terminal of the fourth transistor 265 is low or at a low voltage level, while the input at the first inverter 245 and at the first terminal of the second transistor 240 is high or at a high voltage level. The output of the first inverter is, thus, low or at a low voltage level, while the output of the second inverter 270 is high or at a high voltage level. Accordingly, the first transistor 235 is disabled and the output node 215 is not connected to the supply voltage 250. Likewise, because the first terminal of the second transistor 240 is high or at a high voltage level, the second transistor 240 is enabled and the output node 215 is pulled down to the ground voltage 255. Similarly, the third transistor 260 is enabled and the output node 225 is pulled up to the supply voltage 250. The fourth transistor 265, on the other hand, is disabled.

When the output node 215 is high or at a high voltage value (e.g., storing bit 1) and the output node 225 is low or at a low voltage level (e.g., storing bit 0), the input node 220 is high or at a high voltage level and the input node 230 is low or at a low voltage level. Thus, the input of the first inverter 245 is low and the output of the first inverter is high, which enables the first transistor 235 such that the output node 215 is pulled up to the supply voltage 250. Because the input node 230 is low or at a low voltage level, the second transistor 240 is disabled.

Similarly, the input at the second inverter 270 is high or at a high voltage level and the output of the second inverter is low, which disables the third transistor 260. However, the fourth transistor 265 is enabled and the output node 225 is pulled down to the ground voltage 255.

Because n-type transistors are faster than p-type transistors and because the SRAM cell 200 uses n-type transistors, the GaN transistors in the SRAM cell are able to provide similar functionality with faster read and write speeds compared to traditional Silicon based transistors that use p-type transistors as well. Further, as described below in FIG. 3, the first inverter 245 and the second inverter 270 are each connected to a supply voltage. The supply voltage 250 along with the supply voltage of the first inverter 245 and the second inverter 270 provide the SRAM cell 200 with a dual voltage supply voltage.

Turning to FIG. 3, an example shadow inverter 300 is shown, in accordance with some embodiments of the present disclosure. The shadow inverter 300 may be each of the first inverter 245 and the second inverter 270. The shadow inverter 300 includes a first transistor 305, a second transistor 310, and a third transistor 315 connected between a first voltage level 320 and a second voltage level 325. The second transistor 310 and the third transistor 315 are connected in series between the second voltage level 325, an input node 330, and output node 335. In particular, an input or first terminal (e.g., gate) of the second transistor 310 is connected to the input node 330 and a second terminal (e.g., drain or source) of the second transistor is connected to the output node 335. A third terminal (e.g., source or drain) of the second transistor 310 is connected to a second terminal (e.g., drain or source) of the third transistor 315. An input or first terminal (e.g., gate) of the third transistor 315 is connected to a negative threshold voltage, -VT, 340. A third terminal (e.g., source or drain) of the third transistor 315 is connected to the second voltage level 325. The first voltage level 320 and the second voltage level 325 may each be a supply voltage similar to the supply voltage 250.

Further, an input or first terminal (e.g., gate) of the first transistor 305 is connected to the input node 330, while a second terminal (e.g., source or drain) of the first transistor is connected to the first voltage level 320 and a third terminal (e.g., drain or source) of the first transistor is connected to the output node 335. In some embodiments, the first transistor 305 and the third transistor 315 are both p-type transistors (e.g., P-channel MOS or PMOS), while the second transistor 310 is an n-type transistor. Further, each of the first transistor 305, the second transistor 310, and the third transistor 315 is a GaN transistor, the structure of which is shown and described in FIGS. 8-11C below.

Additionally, because the input or first terminal of the third transistor 315 is connected to the negative threshold voltage 340 (e.g., a low voltage level) and because the third transistor is a p-type transistor that is enabled at a low voltage level, the third transistor is essentially always enabled. The negative threshold voltage 340 may be any negative threshold value that is sufficient to keep the third transistor 315 in an enabled state. In some embodiments, the negative threshold voltage 340 may be a ground voltage level. The third transistor 315 may be used to control or equalize (or substantially equalize) the pull up and pull-down speeds of both the second transistor 310 and the first transistor 305. P-type transistors are slower than n-type transistors. Thus, the first transistor 305, which is p-type, may be slower than the second transistor 310, which is n-type, and accordingly, the first transistor may provide a weaker pull up than the strong pull down provided by the second transistor. By adding the third transistor 315 in series with the second transistor 310, the speed/pull up and pull-down strengths of the first transistor 305 and the second transistor 310 may be equalized. Equalizing the pull up and pull down strengths of the first transistor 305 and the second transistor 310 may be desirable to achieve improved voltage transfer characteristics, as well as reduce the impact on output (e.g., the output node 335, and therefore, the output nodes 215 and 225) of small noise on the input (e.g., the input node 330, and therefore, the input nodes 220 and 230), thereby achieving a larger noise margin and therefore correct functionality of the shadow inverter 300. Thus, the third transistor 315 may be used to control both the pull up speed/strength and the pull-down speed/strength.

When the shadow inverter 300 is connected to the first transistor 235 of FIG. 2, the input node 330 is connected to the input node 230, while the output node 335 is connected to the input or first terminal (e.g., gate) of the first transistor. When the shadow inverter 300 is connected to the third transistor 260, the input node 330 is connected to the input node 220 and the output node 335 is connected to the input or first terminal (e.g., gate) of the third transistor. By virtue of having slower p-type transistors (e.g., the first transistor 305 and the third transistor 315), the first inverter 245 and the second inverter 270 may be somewhat slower than the other transistors (e.g., the first-fourth transistors 235, 240, 260, 265) of the SRAM cell 200. However, because the first inverter 245 and the second inverter 270 are controlling a single fast n-type transistor (e.g., the first transistor 235 and the third transistor 260), the overall speed of the SRAM cell 200 is increased.

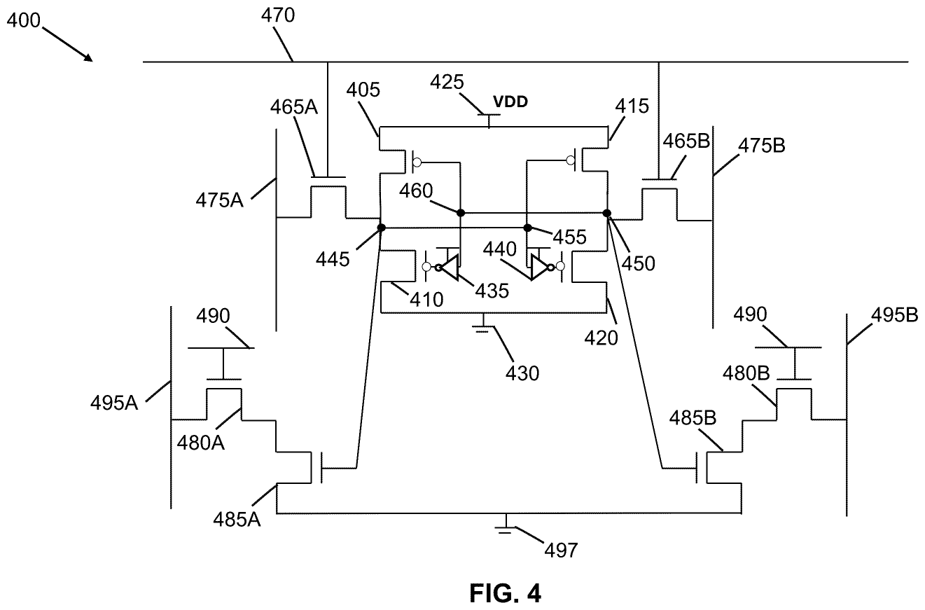

Referring now to FIG. 4, an example SRAM cell 400 of the SRAM array 105 is shown, in accordance with some embodiments of the present disclosure. The SRAM cell 400 provides dual read and write ports. By providing dual read and write ports, data can be read from, and written to, the SRAM cell 400 using separate bit lines and word lines. In particular, a pair of read bit lines and a read word line may be used to read data from the SRAM cell 400 and a pair of write bit lines and a write word line may be used to write data to the SRAM cell. Separate read and write ports of the SRAM cell 400 may allow for simultaneous reading and writing from the SRAM cell 400 in the same cycle. For example, in some embodiments, data may be written to one row (or one column) and data may be read from another row or column simultaneously, thereby increasing the speed of read and write operations. Further, the SRAM cell 400 uses GaN transistors. Thus, the SRAM cell 400 may be used at high or extremely high temperatures. Furthermore, the SRAM cell 400 is configured with a dual voltage supply and provides high write margin and a read disturb free operation.

The SRAM cell 400 includes a first transistor 405, a second transistor 410, a third transistor 415, and a fourth transistor 420 connected between a supply voltage 425 (e.g., similar to the supply voltage 250) and a ground voltage 430 (e.g., similar to the ground voltage 255). The SRAM cell 400 also includes a first inverter 435 and a second inverter 440. The first transistor 405 is connected between the supply voltage 425 and an output node 445. The second transistor 410 is connected between the output node 445 and the ground voltage 430. The third transistor 415 is connected between the supply voltage 425 and an output node 450, while the fourth transistor is connected between the output node 450 and the ground voltage 430. Similar to the SRAM cell 200, the first transistor 405 and the second transistor 410 are cross-coupled with the third transistor 415 and the fourth transistor 420 to form a latch circuit. In particular, the output node 445 is connected to an input node 455 of the third transistor 415 and the fourth transistor 420, while the output node 450 is connected to an input node 460 of the first transistor 405 and the second transistor 410.

In some embodiments, each of the first transistor 405, the second transistor 410, the third transistor 415, and the fourth transistor 420 is a p-type GaN transistor. In some embodiments, the first inverter 435 and the second inverter 440 is also made up of GaN transistors. The first inverter 435 and the second inverter 440 may each be a shadow inverter and have a circuit as shown in the shadow inverter 300. In some embodiments, output (e.g., the output node 335) of the first inverter 435 is connected to a first or input terminal (e.g., gate) of the second transistor 410, while an output (e.g., the output node 335) of the second inverter 440 is connected to a first or input terminal (e.g., gate) of the fourth transistor 420. The input node 460 may be connected to an input (e.g., the input node 330) of the first inverter 435 and the input node 455 may be connected to an input (e.g., the input node 330) of the second inverter 440. Thus, the second transistor 410 is enabled based on the output of the first inverter 435 and the fourth transistor is enabled based on the output of the second inverter 440. Because each of the first transistor 405, the second transistor 410, the third transistor 415, and the fourth transistor 420 is a p-type transistor, each of these transistors is enabled when the gate of that transistor is low or at a low voltage level and disabled when the gate is high or at a high voltage level.

When the output node 445 is low or at a low voltage level (e.g., storing bit 0) and the output node 450 is high or at a high voltage level (e.g., storing bit 1), the input at the second inverter 440 and at the first terminal of the third transistor 415 is low or at the low voltage level and the input at the first inverter 410 and at the first terminal of the first transistor 405 is high or at the high voltage level. Thus, the first transistor 405 is disabled and the third transistor 415 is enabled. Further, the first inverter 410 inverts the high voltage value and the second inverter 440 inverts the low voltage value such that the second transistor 410 is enabled and the fourth transistor 420 is disabled. Therefore, the second transistor 410 pulls the output node 445 down to a low voltage level and the third transistor 415 pulls the output node 450 up to a high voltage level. When the output node 445 is high or at a high voltage level (e.g., storing bit 1) and the output node 450 is low or at a low voltage level (e.g., storing bit 0), the third transistor 415 is disabled and the second inverter 440 inverts the high voltage level and enables the fourth transistor 420 to pull down the output node 450 to a low voltage level. Similarly, the first transistor 405 is enabled and the first inverter 445 inverts the low voltage level to disable the second transistor 410. The first transistor 405 pulls up the output node 445 to a high voltage level.

The SRAM cell 400 also includes a first access transistor 465A and a second access transistor 465B to enable a write operation. In some embodiments, each of the first access transistor 465A and the second access transistor 465B is an n-type GaN transistor. A first or input terminal (e.g., gate) of the first access transistor 465A may be connected to a write word line 470, a second terminal (e.g., source or drain) of the first access transistor is connected to a first write bit line 475A, and a third terminal (e.g., drain or source) of the first access transistor is connected to the output node 445. The first access transistor 465A may be enabled or disabled by asserting or de-asserting, respectively, the write word line 470. When the first access transistor 465A is enabled, the first write bit line 475A is connected to the output node 445 for storing data at that output node. When the first access transistor 465A is disabled, the first write bit line 475A is disconnected from the output node 445 preventing the bit line from writing data to that output node. Similarly, an input or first terminal (e.g., gate) of the second access transistor 465B is connected to the write word line 470, a second terminal (e.g., source or drain) of the second access transistor is connected to a second write bit line 475B, and a third terminal (e.g., drain or source) of the second access transistor is connected to the output node 450. The second write bit line 475B is the inverse of the first write bit line 475A. The second access transistor 465B may be enabled or disabled by asserting or de-asserting, respectively, the write word line 470. When the second access transistor 465B is enabled, the second write bit line 475B is connected to the output node 450 for writing data thereto. When the second access transistor 465B is disabled, the second write bit line 475B is disconnected from the output node 450.

Thus, the first access transistor 465A and the second access transistor 465B are used to write data to the output nodes 445 and 450, respectively. Because the first transistor 405, the second transistor 410, the third transistor 415, and the fourth transistor 420 is each a p-type transistor, the SRAM cell 400 provides a high write margin. In other words, the SRAM cell 400 is able to handle variations in supply voltage, process variations, etc. without compromising data integrity. High write margin in the SRAM cell 400 is particularly possible due to the weaker p-type transistors (e.g., the first transistor 405, the second transistor 410, the third transistor 415, and the fourth transistor 420) and the stronger n-type access transistors (e.g., the first access transistor 465A and the second access transistor 465B). However, because p-type transistors are slower in speed than n-type transistors and because the first transistor 405, the second transistor 410, the third transistor 415, and the fourth transistor 420 are each p-type transistors, the speed of reading data using these transistors may be slower (e.g., relative to the SRAM cell 200 that has n-type transistors). To provide a faster read operation, the SRAM cell 400 includes a separate read port that provides a faster read operation. The separate read port includes a third access transistor 480A connected to a fifth transistor 485A and a fourth access transistor 480B connected to a fifth transistor 485B. A first or input terminal (e.g., gate) of the third access transistor 480A is connected to a read word line 490, a second terminal (e.g., source or drain) of the third access transistor is connected to a first read bit line 495A, and a third terminal (e.g., drain or source) of the third access transistor is connected to a second terminal (e.g., source or drain) of the fifth transistor 485A. A first or input terminal (e.g., gate) of the fifth transistor 485A is connected to the output node 445 and a third terminal (e.g., drain or source) of the fifth transistor is connected to a ground voltage 497 (e.g., similar to the ground voltage 255).

Similarly, an input or first terminal (e.g., gate) of the fourth access transistor 480B is connected to the read word line 490, a second terminal (e.g., source or drain) of the fourth access transistor is connected to a second read bit line 495B, and a third terminal (e.g., drain or source) of the fourth access transistor is connected to a second terminal (e.g., source or drain) of the sixth transistor 480B. The second read bit line 495B is inverse in value of the first read bit line 495A. A first or input terminal (e.g., gate) of the sixth transistor 480B is connected to the output node 450 and a third terminal (e.g., drain or source) of the sixth transistor is connected to the ground voltage 497.

Each of the third access transistor 480B, the fourth access transistor 480B, the fifth transistor 485A, and the sixth transistor 485B is an n-type transistor. Further, each of the third access transistor 480B, the fourth access transistor 480B, the fifth transistor 485A, and the sixth transistor 485B is a GaN transistor. Because n-type transistors are faster than p-type transistors, the third access transistor 480B, the fourth access transistor 480B, the fifth transistor 485A, and the sixth transistor 485B may be used to perform a faster reading operation (e.g., relative to using the first transistor 405 and the third transistor 415 for the reading operation). In particular, the third access transistor 480A may be enabled or disabled by asserting or de-asserting, respectively, the read word line 490. When the third access transistor 480A is enabled, the first read bit line 495A is connected to the fifth transistor 485A. The fifth transistor 485A may be enabled or disabled based on the output node 445. For example, when the output node 445 is at a high voltage level, the fifth transistor 485A may be enabled, and pull the second terminal of the fifth transistor down to a low voltage level, which can be read by the first read bit line 495A. When the output node 445 is at a low voltage level, the fifth transistor 285A is disabled.

Similarly, the fourth access transistor 480B may be enabled or disabled by asserting or de-asserting, respectively, the read word line 490. When the fourth access transistor 480B is enabled, the second read bit line 495B is connected to the sixth transistor 485A. The sixth transistor 485B may be enabled or disabled based on the output node 450. For example, when the output node 450 is at a high voltage level, the sixth transistor 485B may be enabled, and pull the second terminal of the sixth transistor down to a low voltage level, which may be read by the second read bit line 495B. When the output node 450 is at a low voltage level, the sixth transistor 485B is turned off or disabled.

Thus, the third access transistor 480A and the fourth access transistor 480B may be used to read data from the SRAM cell 400. Further, because the read operation is provided through faster and stronger n-type transistors (e.g., the third access transistor 480A, the fourth access transistor 480B, the fifth transistor 485A, and the sixth transistor 485B), and because the output nodes 445, 450 provide an indirect connection (e.g., via the fifth transistor 485A and the sixth transistor 485B) to the first read bit line 495A and the second read bit line 495B, the SRAM cell 400 provides a read disturb free operation (e.g., the unintentional alteration of the state of the SRAM cell 400 during reading is minimized).

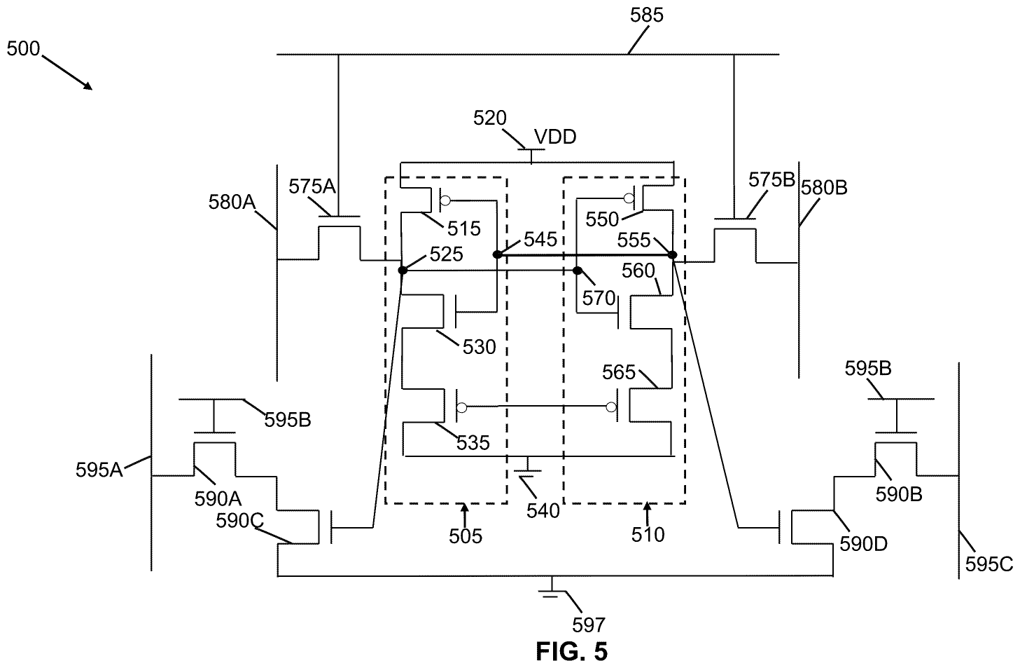

Referring to FIG. 5, an example SRAM cell 500 of the SRAM array 105 is shown, in accordance with some embodiments of the present disclosure. The SRAM cell 500 includes p-type dominant cross-coupled inverters and fewer number of transistors compared to the SRAM cells 300, 400. The SRAM cell 500 provides dual read and write ports like the SRAM cell 400 allowing simultaneous read and write operations in the SRAM cell 500. Further, the SRAM cell 500 uses GaN transistors, and may therefore be used at high or extremely high temperatures. Furthermore, the SRAM cell 400 is configured to provide high write margin and a read disturb free operation while using fewer transistors compared to the SRAM cell 400.

The SRAM cell 500 includes a first inverter 505 and a second inverter 510 cross-coupled to one another. Each of the first inverter 505 and the second inverter 510 has similar circuit as the shadow inverter 300 and operates similar to the shadow inverter 300, and is therefore, not described again in detail. In general, the first inverter 505 includes a first transistor 515 connected between a supply voltage 520 (e.g., similar to the supply voltage 250) and an output node 525, a second transistor 530 connected to that output node and to a third transistor 535, and the third transistor additionally connected to a ground voltage 540 (e.g., similar to the ground voltage 255). In some embodiments, instead of the ground voltage 540, another low voltage value such as that of the second voltage 325 may be used. In some embodiments, instead of the supply voltage, another high voltage value (e.g., the first voltage level 320) may be used. A first or input terminal (e.g., gate) of each of the first transistor 515 and the second transistor 530 is connected to an input node 545. The second inverter 510 includes a fourth transistor 550 connected between the supply voltage 520 and an output node 555, a fifth transistor 560 connected between that output node and a sixth transistor 565, which is additionally connected to the ground voltage 540. An input or first terminal (e.g., gate) of the fourth transistor 550 and the fifth transistor 560 is connected to an input node 570.

The output node 525 is coupled to the input node 570 and the output node 555 is coupled to the input node 545 to form a latch circuit. The first transistor 515, the third transistor 535, the fourth transistor 550, and the sixth transistor 565 are p-type transistors, while the second transistor 530 and the fifth transistor 560 are n-type transistors. Further, each of the first transistor 515, the second transistor 530, the third transistor 535, the fourth transistor 550, the fifth transistor 560, and the sixth transistor 565 is a GaN transistor. The SRAM cell 500 also includes a first access transistor 575A and a second access transistor 575B. The first access transistor 575A is connected to a first write bit line 580A and the second access transistor 575B is connected to a second write bit line 580B (e.g., inverse of the first write bit line 580A). The first access transistor 575A and the second access transistor 575B are enabled by a write word line 585. The operation of the first access transistor 575A and the second access transistor 575B is similar to the operation of the first access transistor 465A and the second access transistor 465B, respectively, described above with respect to the SRAM cell 400. The first access transistor 575A and the second access transistor 575B also enable a write operation, as described with respect to the write operation in the SRAM cell 400.

The third transistor 535 and the sixth transistor 565 may be coupled to each other in some embodiments. For example, in some embodiments, a first or input terminal (e.g., gate) of the third transistor 535 may be connected to a first or input terminal (e.g., gate) of the sixth transistor 565. In some embodiments, the first terminals of the third transistor 535 and the sixth transistor 565 may be connected to a negative voltage threshold to essentially keep those transistors enabled at all times. In some embodiments, the third transistor 535 and the sixth transistor 565 may be connected via power gating instead. In some embodiments, the third transistor 535 and the sixth transistor 565 may be used to reduce leakage current. For example, in some embodiments, the first terminals of the third transistor 535 and the sixth transistor 565 may be connected to a high voltage level, thereby essentially disabling the SRAM cell 500.

Further, like the SRAM cell 400, the SRAM cell 500 uses p-type transistors in the pull-up and the pull-down networks. Thus, the read speed in the SRAM cell 500 may be slow. To increase the read speed, like the SRAM cell 400, the SRAM cell 500 includes a separate read port. This read port includes a third access transistor 590A, a fourth access transistor 590B, a seventh transistor 590C, and an eighth transistor 590D. The third access transistor 590A is connected to a first read bit line 595A, to a read word line 595B, and to the seventh transistor 590C. The seventh transistor 590C is also connected to a ground voltage 597 (e.g., similar to the ground voltage 255). The fourth access transistor 590B is connected to a second read bit line 595C (e.g., inverse of the first read bit line 595A), to the read word line 595B, and to the eighth transistor 590D. The eighth transistor 590D is connected to the ground voltage 597. The read port operates like the read port of the SRAM 400, and is therefore, not described again.

Thus, the SRAM cell 500, like the SRAM cell 400, provides separate read and write ports. The read and write operation in the SRAM cell 500 is like the read and write operation of the SRAM cell 400 but with using fewer transistors, and particularly, using four fewer transistors.

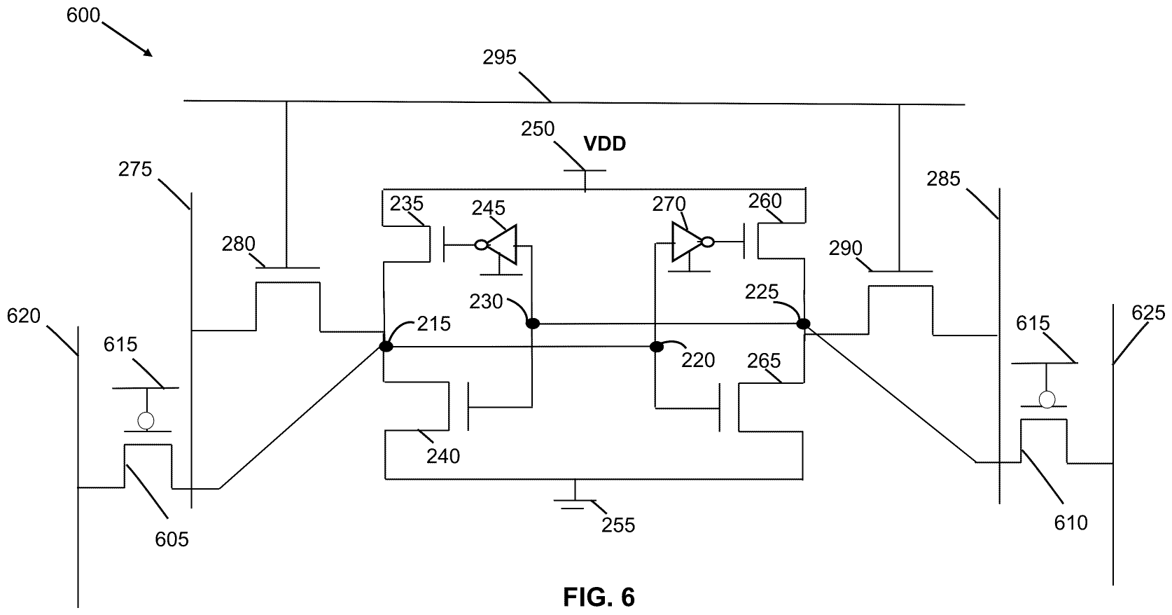

Turning to FIG. 6, an example SRAM cell 600 of the SRAM array 105 is shown, in accordance with some embodiments of the present disclosure. The SRAM cell 600 is a variation of the SRAM cell 200. While the SRAM cell 200 provides a single read and write port, the SRAM cell 600 also provides dual read and write ports like the SRAM cell 400, 500, thereby allowing for simultaneous reading and writing operations in a single cycle. A single read and write port means that the read operation and the write operation are performed using the same bit lines and the word line. Thus, in each cycle of a single read and write port, either a write operation or a read operation may be performed. Further, the SRAM cell 600 uses GaN transistors, which allows the SRAM cell to be used at very high or extremely high temperatures. Furthermore, the SRAM cell 600 is configured with a dual voltage supply and provides high write margin and a read disturb free operation.

FIG. 6 in particular shows how the SRAM cell 200 may be modified to provide the dual real and write port. In particular, for providing a dual read and write port, the first bit line 275 and the second bit line 285 may be considered write bit lines and the word line 295 may be considered a write word line. The first bit line 275 and the second bit line 285, as well as the word line 295 may be used to write data to the output nodes 215 and 225, and thus, serve as the write port. To provide a separate read port, the output node 215 may be connected to a third access transistor 605 and the output node 225 may be connected to a fourth access transistor 610. In particular, a first or input terminal (e.g., gate) of the third access transistor 605 may be connected to a read word line 615, a second terminal (e.g., source or rain) of the third access transistor may be connected to a first read bit line 620, and a third terminal (e.g., drain or source) of the third access transistor may be connected to the output node 215. Similarly, a first or input terminal (e.g., gate) of the fourth access transistor 610 may be connected to the read word line 615, a second terminal (e.g., source or drain) of the fourth access transistor may be connected to a second read bit line 625 (e.g., inverse of the first read bit line 620), and a third terminal (e.g., drain or source) of the fourth access transistor may be connected to the output node 225.

The third access transistor 605 and the fourth access transistor 610 may each a GaN transistor, and in particular, a p-type GaN transistor. By asserting or de-asserting the read word line 615, the first access transistor 605 and the second access transistor 610 may be enabled or disabled, respectively. When enabled, the first read bit line 620 may be connected to the output node 215 to read the data stored at that node and the second bit line 625 may be connected to the output node 225 to read the data stored at that node. When disabled, the first access transistor 605 and the second access transistor 610 prevent access of the first bit line 620 and the second bit line 625, respectively, to the output nodes 215, 225, respectively. Similar to the SRAM cells 400, 500, the SRAM cell 600 provides a high write margin and a read disturb free operation. However, unlike the SRAM cells 400, 500 that use faster n-type transistors, the SRAM cell 600 may provide a somewhat slower read operation due to use of p-type transistors. However, the read port of the SRAM cell 600 uses fewer transistors than the read ports of the SRAM cells 400, 500, thereby simplifying the layout design of SRAM cell 600.

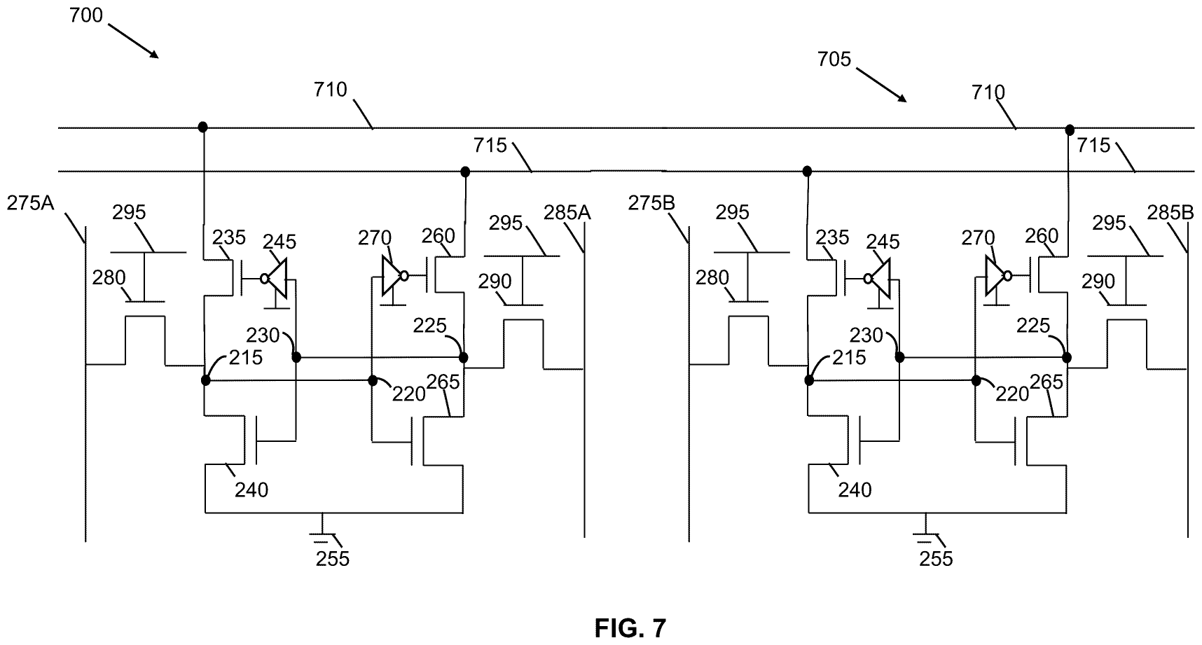

Referring to FIG. 7, a first SRAM cell 700 and a second SRAM cell 705 of the SRAM array 105 are shown, in accordance with some embodiments of the present disclosure. Each of the first SRAM cell 700 and the second SRAM cell 705 provides another variation of the SRAM cell 200. Each of the first SRAM cell 700 and the second SRAM cell 705 provides a Read Only Memory (ROM) embedded Random Access Memory (RAM). In particular, each of the first SRAM cell 700 and the second SRAM cell 705 may be used as both RAM and ROM. Although two SRAM cells (e.g., the first SRAM cell 700 and the second SRAM cell 705) connected in the same row (e.g., connected to the same word line 295) are shown in FIG. 7, in other embodiments, any number of SRAM cells may be connected in the row direction and the column direction depending on the size of the memory array that is desired. Further, in the column direction, each of the first SRAM cell 700 and the second SRAM cell 705 may be connected to different bit lines. For example, as shown in FIG. 7, the first SRAM cell 700 and the second SRAM cell 705 are in separate columns. Thus, the first SRAM cell 700 may be connected to first bit line 275A and second bit line 285A, while the second SRAM cell 705 may be connected to first bit line 275B and second bit line 285B. As with the bit lines described above, the second bit line 285A may be inverse of the first bit line 275A and the second bit line 285B may be inverse of the first bit line 275B.

In contrast to the SRAM cell 200 in which one terminal of each of the first transistor 235 and the third transistor 260 is connected to the same supply voltage 250, in the first SRAM cell 700 and the second SRAM cell 705, those transistors are connected to separate supply voltages. For example, as shown in FIG. 7, in some embodiments, the first transistor 235 of the first SRAM cell 700 is connected to a first supply voltage 710 and the third transistor 260 of the first SRAM cell is connected to a second supply voltage 715. Each of the first supply voltage 710 and the second supply voltage 715 may be a high voltage level (e.g., VDD). In some embodiments, each of the first supply voltage 710 and the second supply voltage 715 may have the same supply voltage level. In other embodiments, the first supply voltage 710 and the second supply voltage 715 may have different supply voltage levels. For example, in some embodiments, the first voltage supply 710 may be 3.3 volts and the second supply voltage 715 may be 5 volts. It is to be understood that these voltage levels are only an example and not intended to be limiting in any way.

Further, in some embodiments, the first transistor 235 of the second SRAM cell 705 is connected to the second supply voltage 715 and the third transistor 260 of the second SRAM cell is connected to the first supply voltage 710. Thus, the first transistor 235 of alternate SRAM cells are connected to the first supply voltage 710. For example, if a third SRAM cell is provided in the same row adjacent the second SRAM cell 710 (e.g., away from the SRAM cell 700), the first transistor of the third SRAM cell would be connected to the first supply voltage 710. In some embodiments, a similar alternating pattern may be provided for adjacent SRAM cells in the same column. For example, if an SRAM cell is provided in the same column as the first SRAM cell 700 and adjacent to the first SRAM cell, the first transistor of that SRAM cell may be connected to the second supply voltage 715. A similar alternating pattern may be present for the third transistor 260.

Moreover, in some embodiments, another pattern may be more feasible depending on the value to be stored in the ROM. In some embodiments, the connections to the first supply voltage 710 and the second supply voltage 715 may be determined at the time of manufacturing based on the value to be stored in the ROM. For example, in some embodiments, to store a bit 1 in an SRAM cell (e.g., either the first SRAM cell 700 or the second SRAM cell 705), the first transistor 235 may be connected to the first supply voltage 710 and the third transistor 260 may be connected to the second supply voltage 715. In some embodiments, to store a bit 0 in an SRAM cell (e.g., either the first SRAM cell 700 or the second SRAM cell 705), the first transistor 235 may be connected to the second supply voltage 715 and the third transistor 260 may be connected to the first supply voltage 710. In other embodiments, the first transistor 235 may be connected to the first supply voltage 710 and the third transistor 260 may be connected to the second supply voltage 715 to store a bit 1 and the first transistor may be connected to the second supply voltage and the third transistor may be connected to the first supply voltage to store a bit 1. Thus, depending on the value to be stored in the ROM, the connection of the first transistor 235 and the third transistor 260 to the first supply voltage 710 and the second supply voltage 715 may vary.

As indicated above, each of the first SRAM cell 700 and the second SRAM cell 705 may be used as both RAM and ROM. To use the first SRAM cell 700 and the second SRAM cell 705 as RAM, voltage at the first supply voltage 710 and the second supply voltage 715 may be applied at the same time. When applied at the same time, each of the first SRAM cell 700 and the second SRAM cell 705 essentially operates like the SRAM cell 200. To operate the first SRAM cell 700 and the second SRAM cell 705 as a ROM, in some embodiments, the application of voltage at the first supply voltage 710 and the second supply voltage 715 may be staggered. For example, in some embodiments, voltage may be applied at the first supply voltage 710 at time A and then voltage may be applied at the second supply voltage 715 at time B. Alternatively, in some embodiments, voltage may be applied at the second supply voltage 715 at time A and then voltage may be applied at the first supply voltage 710 at time B. In some embodiments, the time interval between time A and time B may vary depending on the size of the memory array. In some embodiments, a minimum time interval between time A and time B may be 1 nanosecond. In other embodiments, the minimum time interval between time A and time B may be in the range of 50 nanoseconds to 1 microsecond.

When the voltage on the first supply voltage 710 and the second supply voltage 715 is at ground (e.g., 0V), the first SRAM cell 700 and the second SRAM cell 710 are not operating and the data stored in those SRAM cells is lost. However, when the application of voltage on the first supply voltage 710 and the second supply voltage 715 is staggered (e.g., applied at a time difference), data is written at the output node 215 or 225 to function as a ROM. For example, when a first voltage level (e.g., VDD voltage) is applied to the first supply voltage 710, the output node 215 of the first SRAM cell 700 and the output node 225 of the second SRAM cell 705 store a high bit level (e.g., ‘1’). Then, when a second voltage level (e.g., VDD voltage) is applied to the second supply voltage 715 after a time interval, both of the first SRAM cell 700 and the second SRAM cell 705 are functioning again with a stored value in each SRAM cell (e.g., the output node 215 of the first SRAM cell storing a 1, the output node 225 of the first SRAM cell storing a 0, the output node 215 of the second SRAM cell storing a 0, and the output node 225 of the second SRAM cell storing a 1).

Thus, the first SRAM cell 700 and the second SRAM cell 705 provide both RAM and ROM functionality. Voltage may be applied at the same time on the first supply voltage 710 and the second supply voltage 715 to provide a read and write RAM functionality, while the application of voltage may be staggered on the first supply voltage and the second supply voltage to provide a ROM functionality. In some embodiments, the control circuit in the SRAM device 100 may be used to control the switching between the RAM and ROM functionalities. For example, in some embodiments, the control circuit may receive an indication to use the first SRAM cell 700 and the second SRAM cell 705 as either a RAM or ROM. Responsive to receiving the indication, the control circuit may control the application of voltage at the first supply voltage 710 and the second supply voltage 715. For example, responsive to receiving an indication to use the first SRAM cell 700 and the second SRAM cell 705 as a RAM, the control circuit may apply voltage to the first supply voltage 710 and the second supply voltage 715 simultaneously. Responsive to receiving an indication to use the first SRAM cell 700 and the second SRAM cell 705 as a ROM, the control circuit may apply voltage to the first supply voltage 710 and the second supply voltage 715 in a staggered fashion (e.g., separate the application of voltage by a time interval). Thus, in each cycle the first SRAM cell 700 and the second SRAM cell 705 may both be used as either a RAM or ROM.

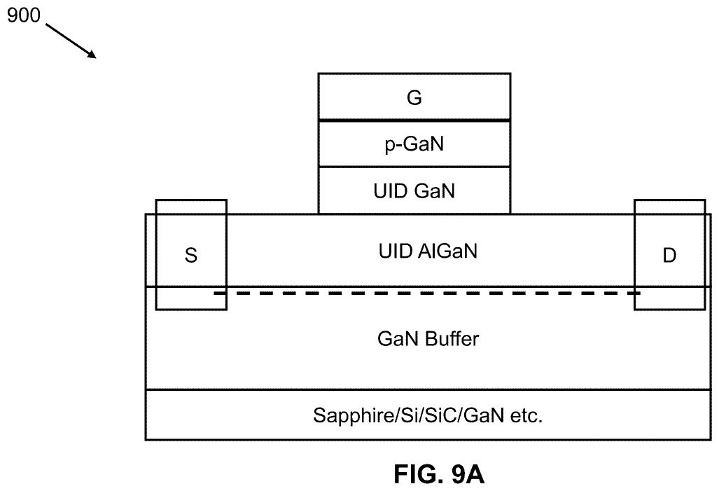

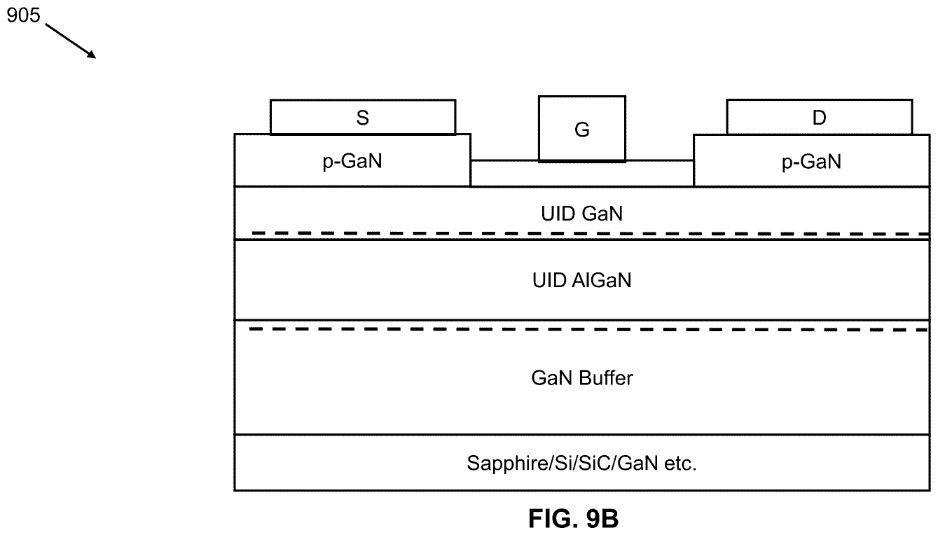

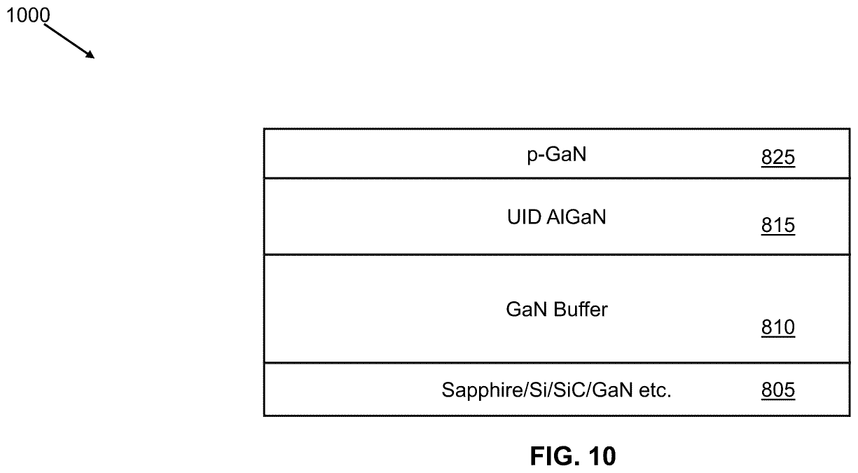

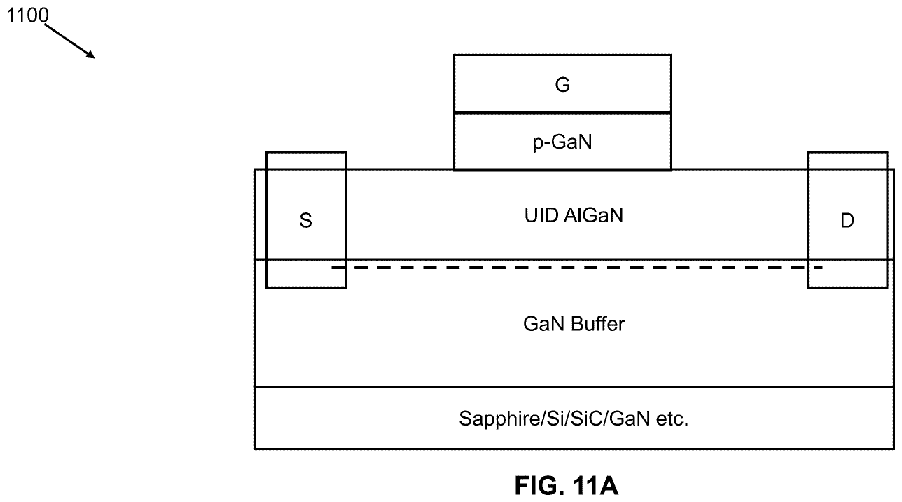

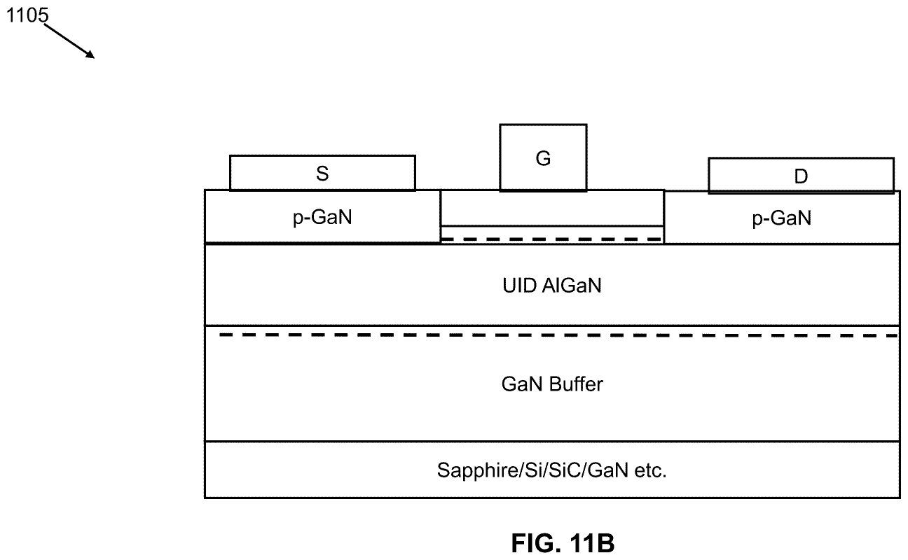

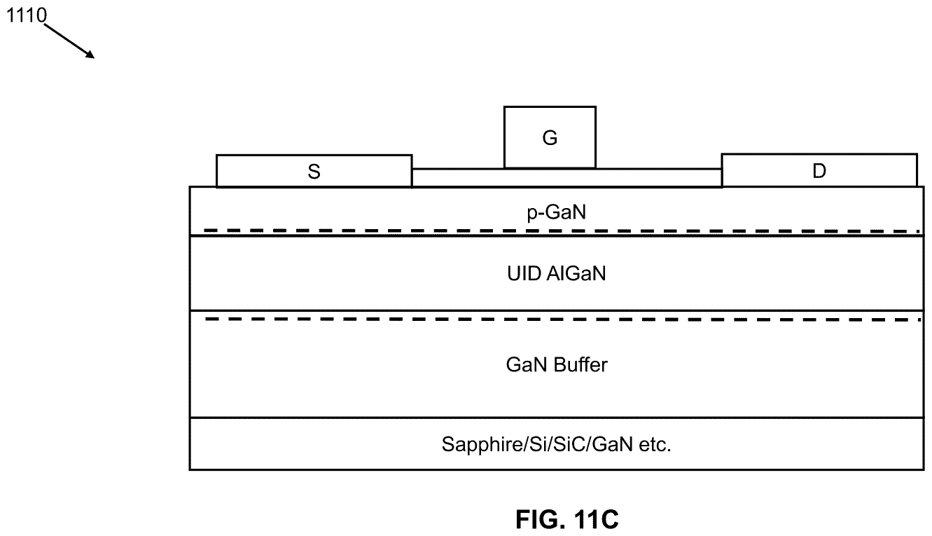

Turning now to FIGS. 8-11C, example structures of a GaN transistor that may be used for the various transistors described above are shown, in accordance with some embodiments of the present disclosure. Specifically, FIGS. 8-9B show one example structure of a GaN transistor and FIGS. 10-11C show another example structure of the GaN transistor. In general, and similar to a silicon transistor, a GaN Field Effect Transistor (FET) (referred to herein as a GaN transistor) may include three terminals: source, drain, and gate. A GaN transistor may be a High Electron Mobility Transistor (HEMT) device. In particular, a GaN transistor may use a two-dimensional electron gas (2DEG) at a junction created between materials with different band gaps to provide the HEMT functionality. The 2DEG may act as a conduction channel between the source and drain of a GaN transistor. HEMT based GaN transistors may provide a faster switching speed (e.g., capable of operating at higher frequencies), may handle higher power levels more efficiently, are more energy efficient, may withstand very high or extremely high temperatures, and otherwise have superior material properties compared to silicon transistors. The GaN transistors suitable for use for the SRAM cells described herein may be either depletion mode (d-GaN) that are normally on and require negative voltage at the gate to turn off or enhancement mode (e-GaN) which are normally off and turned on by positive voltage applied at the gate.

Referring specifically to FIG. 8, an example structure of a GaN transistor 800 may include a substrate layer 805 over which various other layers may be formed. In some embodiments, the substrate layer 805 may be a sapphire, silicon, silicon carbide, or gallium nitride layer. In other embodiments, other materials that are suitable to use for a GaN transistor may be used to form the substrate 805. The substrate 805 may be used to provide mechanical strength to the GaN transistor and serve as a base to form the other layers thereover. A buffer layer 810 may be deposited over the substrate 805. In some embodiments, the buffer layer 810 may be a gallium nitride buffer layer. In other embodiments, other suitable materials may be used for the buffer layer 810. The buffer layer 810 may be used to manage tensile stress (e.g., lattice mismatch) between silicon in the substrate layer 805 and the various GaN layers above the substrate layer, and limit leakage current, thereby ensuring reliable transistor operation.

A first Unintentionally Doped (UID) layer 815 and a second UID layer 820 may be deposited over the buffer layer 810. In some embodiments, the first UID layer 815 may be an aluminum gallium nitride (AlGaN) barrier layer. In some embodiments, the second UID layer 820 may be a gallium nitride (GaN) barrier layer. In other embodiments, other materials may be used for either or both of the first UID layer 815 and the second UID layer 820. The first UID layer 815 and the second UID layer 820 provide/form the 2DEG interface or junction having a high charge density and mobility. In some embodiments, the source, gate, and drain terminals may be formed in the first UID layer 815 and/or the second UID layer 820 to control the current flow. FIG. 9A shows an example of an n-channel GaN transistor 900 in which the source and drain are formed in the first UID layer 815. The n-channel GaN transistor 900 may be either normally-on (e.g., depletion mode) or normally-off (e.g., enhancement mode). A cap layer 825 may be deposited over the second UID layer 820. In some embodiments, the cap layer 825 may be a p-doped gallium nitride (GaN) layer. In other embodiments, other types of suitable materials may be used for the cap layer 825. Although not shown, in some embodiments, the GaN transistor 800 may include one or more dielectric layers, passivation layers, field plate layers, etc.

FIG. 9B shows another example of forming the source, drain, and gate terminals. In particular, FIG. 9B shows a p-channel GaN transistor 905 in which the source and drain terminals are formed in the cap layer 825, while the gate terminal is formed on a dielectric layer deposited over the second UID layer 820. The p-channel GaN transistor 905 may be either normally-on (e.g., depletion mode) or normally-off (e.g., enhancement mode).

FIG. 10 shows another example of a GaN transistor 1000. Similar to the GaN transistor 800, the GaN transistor 1000 has the substrate layer 805, the buffer layer 810, the first UID layer 815, and the cap layer 825. Unlike the GaN transistor 800, the GaN transistor 1000 has a single UID layer. FIG. 11A shows an example of an n-channel GaN transistor 1100 in which the source and drain are formed in the first UID layer 815. The n-channel GaN transistor 900 may be either normally-on (e.g., depletion mode) or normally-off (e.g., enhancement mode). FIG. 11B shows a p-channel GaN transistor 1105 in which the source and drain terminals are formed in the cap layer 825, while the gate terminal is formed on a dielectric layer deposited over the first UID layer 815. The p-channel GaN transistor 1105 may be either normally-on (e.g., depletion mode) or normally-off (e.g., enhancement mode). FIG. 11C shows another p-channel GaN transistor 1110 in which the source and drain terminals are formed in the cap layer 825, and the gate terminal is formed on a dielectric layer deposited over the cap layer. The p-channel GaN transistor 1110 may be either normally-on (e.g., depletion mode) or normally-off (e.g., enhancement mode).

Although example structures of GaN transistors are shown herein, in other embodiments, other suitable structures of the GaN transistors may be used in the SRAM cells disclosed herein.

As used herein, the term “mount” includes join, unite, connect, couple, associate, insert, hang, hold, affix, attach, fasten, bind, paste, secure, bolt, screw, rivet, solder, weld, glue, form over, form in, layer, mold, rest on, rest against, etch, abut, and other like terms. The phrases “mounted on”, “mounted to”, and equivalent phrases indicate any interior or exterior portion of the element referenced. These phrases also encompass direct mounting (in which the referenced elements are in direct contact) and indirect mounting (in which the referenced elements are not in direct contact but are connected through an intermediate element). Elements referenced as mounted to each other herein may further be integrally formed together, for example, using a molding or a thermoforming process as understood by a person of skill in the art. As a result, elements described herein as being mounted to each other need not be discrete structural elements. The elements may be mounted permanently, removably, or releasably unless specified otherwise.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”. Still further, using “and” or “or” in the detailed description is intended to include “and/or” unless specifically indicated otherwise. The illustrative embodiments may be implemented as a method, apparatus, or article of manufacture using standard programming and/or engineering techniques to produce software, firmware, hardware, or any combination thereof to control a computer to implement the disclosed embodiments.

Any directional references used herein, such as left-side, right-side, top, bottom, back, front, up, down, above, below, etc., are for illustration only based on the orientation in the drawings selected to describe the illustrative embodiments.

The foregoing description of illustrative embodiments of the disclosed subject matter has been presented for purposes of illustration and of description. It is not intended to be exhaustive or to limit the disclosed subject matter to the precise form disclosed, and modifications and variations are possible in light of the above teachings or may be acquired from practice of the disclosed subject matter. The embodiments were chosen and described in order to explain the principles of the disclosed subject matter and as practical applications of the disclosed subject matter to enable one skilled in the art to utilize the disclosed subject matter in various embodiments and with various modifications as suited to the particular use contemplated.

What is claimed is:

1. A Static Random Access Memory (SRAM) cell comprising:
a first transistor connected between at least one supply voltage and a first output node;
a second transistor connected between the first output node and a ground voltage;
a third transistor connected between the at least one supply voltage and a second output node;
a fourth transistor connected between the second output node and the ground voltage;
a first inverter having a first inverter input and a first inverter output, the first inverter input connected to a first input node and the first inverter output connected to either the first transistor or the second transistor;
a second inverter having a second inverter input and a second inverter output, the second inverter input connected to a second input node and the second inverter output connected to either the third transistor or the fourth transistor;
a first access transistor connected between a first bit line and the first output node; and
a second access transistor connected between a second bit line and the second output node;
wherein each of the first transistor, the second transistor, the third transistor, the fourth transistor, the first access transistor, and the second access transistor is a gallium nitride (GaN) transistor; and
wherein each of the first inverter and the second inverter comprises GaN transistors.

2. The SRAM cell of claim 1, wherein each of the first transistor, the second transistor, the third transistor, and the fourth transistor is an n-type GaN transistor, and wherein the first inverter output is connected to the first transistor and the second inverter output is connected to the third transistor.

3. The SRAM cell of claim 1, wherein each of the first transistor, the second transistor, the third transistor, and the fourth transistor is a p-type GaN transistor, and wherein the first inverter output is connected to the second transistor and the second inverter output is connected to the fourth transistor.

4. The SRAM cell of claim 1, wherein each of the first inverter and the second inverter comprises:
a first p-type GaN transistor connected to a second supply voltage;
an n-type GaN transistor connected to the first p-type GaN transistor; and
a second p-type GaN transistor connected to the n-type GaN transistor and a second ground voltage.

5. The SRAM cell of claim 4, wherein the second p-type GaN transistor is connected to a negative voltage threshold to keep the p-type GaN transistor always enabled.

6. The SRAM cell of claim 1, further comprising:
a fifth transistor connected to the first output node;
a third access transistor between the fifth transistor and a third bit line;
a sixth transistor connected to the second output node; and
a fourth access transistor between the sixth transistor and a fourth bit line,
wherein each of the fifth transistor, the sixth transistor, the third access transistor, and the fourth access transistor is a GaN transistor;
wherein the first access transistor and the second access transistor are connected to a write word line to write data to the first output node and the second output node via the first bit line and the second bit line; and
wherein the third access transistor and the fourth access transistor are connected to a read word line to read data from the first output node and the second output node via the third bit line and the fourth bit line.

7. The SRAM cell of claim 6, wherein each of the fifth transistor, the sixth transistor, the third access transistor, and the fourth access transistor is an n-type GaN transistor.

8. The SRAM cell of claim 1, further comprising:
a third access transistor connected between the first output node and a third bit line;
a fourth access transistor connected between the second output node and a fourth bit line;
wherein each of the third access transistor and the fourth access transistor is a p-type GaN transistor;
wherein the first access transistor and the second access transistor are connected to a write word line to write data to the first output node and the second output node via the first bit line and the second bit line; and
wherein the third access transistor and the fourth access transistor are connected to a read word line to read data from the first output node and the second output node via the third bit line and the fourth bit line.

9. The SRAM cell of claim 1, wherein the at least one supply voltage comprises a first supply voltage and a second supply voltage, wherein the first transistor is connected to the first supply voltage and the third transistor is connected to the second supply voltage, and wherein application of voltage at the first supply voltage and the second supply voltage is separated by a time interval to provide a read only memory functionality in the SRAM cell.

10. The SRAM cell of claim 1, wherein the at least one supply voltage comprises a first supply voltage and a second supply voltage, wherein the first transistor is connected to the first supply voltage and the third transistor is connected to the second supply voltage, and wherein voltage is applied simultaneously at the first supply voltage and the second supply voltage to provide a random access memory functionality in the SRAM cell.

11. A Static Random Access Memory (SRAM) array comprising:
a plurality of SRAM cells arranged in a plurality of rows and a plurality of columns, each of the plurality of SRAM cells comprising:
a first transistor connected between at least one supply voltage and a first output node;
a second transistor connected between the first output node and a ground voltage;
a third transistor connected between the at least one supply voltage and a second output node;
a fourth transistor connected between the second output node and the ground voltage;
a first inverter having a first inverter input and a first inverter output, the first inverter input connected to a first input node and the first inverter output connected to either the first transistor or the second transistor;
a second inverter having a second inverter input and a second inverter output, the second inverter input connected to a second input node and the second inverter output connected to either the third transistor or the fourth transistor;
a first access transistor connected between a first bit line and the first output node; and
a second access transistor connected between a second bit line and the second output node;
wherein each of the first transistor, the second transistor, the third transistor, the fourth transistor, the first access transistor, and the second access transistor is a gallium nitride (GaN) transistor; and
wherein each of the first inverter and the second inverter comprises GaN transistors.

12. The SRAM array of claim 11, wherein:
when each of the first transistor, the second transistor, the third transistor, and the fourth transistor is an n-type GaN transistor, the first inverter output is connected to the first transistor and the second inverter output is connected to the third transistor; and
when each of the first transistor, the second transistor, the third transistor, and the fourth transistor is a p-type GaN transistor, the first inverter output is connected to the second transistor and the second inverter output is connected to the fourth transistor.

13. The SRAM array of claim 11, wherein each of the first inverter and the second inverter comprises:
a first p-type GaN transistor connected to a second supply voltage;
an n-type GaN transistor connected to the first p-type GaN transistor; and
a second p-type GaN transistor connected to the n-type GaN transistor and a second ground voltage, wherein the second p-type GaN transistor is connected to a negative voltage threshold to keep the second p-type GaN transistor always enabled.

14. The SRAM array of claim 11, further comprising:
a fifth transistor connected to the first output node;
a third access transistor between the fifth transistor and a third bit line;
a sixth transistor connected to the second output node; and
a fourth access transistor between the sixth transistor and a fourth bit line,
wherein each of the fifth transistor, the sixth transistor, the third access transistor, and the fourth access transistor is a GaN transistor;
wherein each of the fifth transistor, the sixth transistor, the third access transistor, and the fourth access transistor is an n-type GaN transistor;
wherein the first access transistor and the second access transistor are connected to a write word line to write data to the first output node and the second output node via the first bit line and the second bit line; and
wherein the third access transistor and the fourth access transistor are connected to a read word line to read data from the first output node and the second output node via the third bit line and the fourth bit line.

15. The SRAM array of claim 11, further comprising:
a third access transistor connected between the first output node and a third bit line;
a fourth access transistor connected between the second output node and a fourth bit line;
wherein each of the third access transistor and the fourth access transistor is a p-type GaN transistor;
wherein the first access transistor and the second access transistor are connected to a write word line to write data to the first output node and the second output node via the first bit line and the second bit line; and
wherein the third access transistor and the fourth access transistor are connected to a read word line to read data from the first output node and the second output node via the third bit line and the fourth bit line.

16. The SRAM cell of claim 1, wherein the at least one supply voltage comprises a first supply voltage and a second supply voltage, wherein the first transistor is connected to the first supply voltage and the third transistor is connected to the second supply voltage, wherein application of voltage at the first supply voltage and the second supply voltage is separated by a time interval to provide a read only memory functionality in the SRAM cell, and wherein voltage is applied simultaneously at the first supply voltage and the second supply voltage to provide a random access memory functionality in the SRAM cell.

17. A Static Random Access Memory (SRAM) cell comprising:
a first inverter comprising:
a first transistor connected between a supply voltage and a first output node;
a second transistor connected to the first transistor via the first output node; and
a third transistor connected between the second transistor and a ground voltage;
a second inverter comprising:
a fourth transistor connected between the supply voltage and a second output node;
a fifth transistor connected to the fourth transistor via the second output node; and
a sixth transistor connected between the fifth transistor and the ground voltage;
a first access transistor connected between the first output node and a first bit line; and
a second access transistor connected between the second output node and a second bit line;
wherein the third transistor and the sixth transistor are always enabled; and
wherein each of the first transistor, the second transistor, the third transistor, the fourth transistor, the fifth transistor, the sixth transistor, the first access transistor, and the second access transistor is a gallium nitride (GaN) transistor.

18. The SRAM cell of claim 17, further comprising:
a seventh transistor connected to the first output node;
a third access transistor between the fifth transistor and a third bit line;
an eighth transistor connected to the second output node; and
a fourth access transistor between the sixth transistor and a fourth bit line,
wherein each of the seventh transistor, the eighth transistor, the third access transistor, and the fourth access transistor is a GaN transistor;
wherein the first access transistor and the second access transistor are connected to a write word line to write data to the first output node and the second output node via the first bit line and the second bit line; and
wherein the third access transistor and the fourth access transistor are connected to a read word line to read data from the first output node and the second output node via the third bit line and the fourth bit line.

19. The SRAM cell of claim 18, wherein each of the seventh transistor, the eighth transistor, the third access transistor, and the fourth access transistor is an n-type GaN transistor.

20. The SRAM cell of claim 17, wherein each of the first transistor, the third transistor, the fourth transistor, and the sixth transistor is a p-type transistor, and wherein each of the second transistor, the fifth transistor, the first access transistor, and the second access transistor is an n-type transistor.
